(19) United States
(12) Patent Application Publication
(10) Pub. No.: US 2019/0137544 A1
(43) Pub. Date: May 9, 2019

(54) PROBE ASSEMBLY AND ENGAGED-TYPE CAPACITIVE PROBE THEREOF

(71) Applicant: CHUNGHWA PRECISION TEST TECH. CO., LTD., Taoyuan City (TW)

(72) Inventors: Chih-Peng Hsieh, Taipei City (TW); Wei-Jhih Su, Taichung City (TW)

(21) Appl. No.: 15/875,783

(22) Filed: Jan. 19, 2018

(30) Foreign Application Priority Data
Nov. 3, 2017 (TW) 106138112

(51) Int. Cl. G01R 1/073; G01R 1/067; G01R 15/16

(52) U.S. Cl. CPC G01R 1/07307; G01R 15/16; G01R 1/06738

(57) ABSTRACT

The instant disclosure provides a probe assembly and an engaged-type capacitive probe thereof. The engaged-type capacitive probe includes a probe structure, a conductive structure and a dielectric structure. The probe structure has a probe body and a first engaging portion disposed on the probe body. The conductive structure is disposed on one side of the probe structure and has a second engaging portion corresponding to the first engaging portion. The conductive structure is disposed on the first engaging portion of the probe structure through the second engaging portion. The dielectric structure is disposed between the probe structure and the conductive structure.

### BACKGROUND

1. Technical Field

The instant disclosure relates to a probe assembly and an engaged-type capacitive probe thereof, and in particular, to a probe assembly and an engaged-type capacitive probe thereof for a probe card of a chip.

2. Description of Related Art

When performing high-speed signal tests, the core power of a conventional System on Chip (SoC) often has too high of a target impedance value at the used frequency point. Such a problem may be related to the probe card, the transfer substrate, the probe seat or the chip probe. Therefore, the existing solution mostly focuses on the optimization of the transfer substrate, i.e., using a suitable number of decouple capacitors to improve the target impedance value of the power delivery network (PDN). However, even if such an approach can allow the transfer substrate to have a desired impedance value, the overall power delivery network would not be able to be effectively controlled due to the large distance between the transfer substrate and the end to be measured.

Therefore, there is a need to provide a probe assembly and a capacitive probe thereof which are able to reduce the power impedance at the resonant frequency point when performing application tests of the high speed system on chip and to increase the performance of the power delivery network for overcoming the above disadvantages.

### SUMMARY

An object of the instant disclosure is to provide a probe assembly and an engaged-type capacitive probe thereof for effectively reducing the power impedance of the resonant frequency point and increasing the performance of the power delivery network.

An embodiment of the instant disclosure provides an engaged-type capacitive probe including a probe structure, a conductive structure and a dielectric structure. The probe structure has a probe body and a first engaging portion disposed on the probe body. The conductive structure is disposed at one side of the probe structure. The conductive structure has a second engaging portion corresponding to the first engaging portion, and the conductive structure is disposed on the first engaging portion of the probe structure through the second engaging portion. The dielectric structure is disposed between the probe structure and the conductive structure.

Another embodiment of the instant disclosure provides a probe assembly, including a transfer board, a probe bearing seat and a plurality of engaged-type capacitive probes. The transfer board has a plurality of accommodating grooves. The probe bearing seat is disposed on the transfer board and the plurality of engaged-type capacitive probes are disposed on the probe bearing seat and respectively in the plurality of accommodating grooves. Each of the engaged-type capacitive probes includes a probe structure, a conductive structure and a dielectric structure. The probe structure has a probe body and a first engaging portion disposed on the probe body. The conductive structure is disposed at one side of the probe structure, and has a second engaging portion corresponding to the first engaging portion. The conductive structure is disposed on the first engaging portion of the probe structure through the second engaging portion. The dielectric structure is disposed between the first engaging portion of the probe structure and the second engaging portion of the conductive structure.

One of the advantages of the instant disclosure resides in that the probe assembly and the engaged-type capacitive probe thereof can optimize the target impedance value and increase the performance of the power delivery network based on the technical feature of “the dielectric structure is disposed between the first engaging portion of the probe structure and the second engaging portion of the conductive structure”.

In order to further understand the techniques, means and effects of the instant disclosure, the following detailed descriptions and appended drawings are hereby referred to, such that, and through which, the purposes, features and aspects of the instant disclosure can be thoroughly and concretely appreciated; however, the appended drawings are merely provided for reference and illustration, without any intention to be used for limiting the instant disclosure.

### BRIEF DESCRIPTION OF THE DRAWINGS

The accompanying drawings are included to provide a further understanding of the instant disclosure, and are incorporated in and constitute a part of this specification. The drawings illustrate exemplary embodiments of the instant disclosure and, together with the description, serve to explain the principles of the instant disclosure.

FIG. 1 is an exploded perspective view of an engaged-type capacitive probe of a first embodiment of the instant disclosure.

FIG. 2 is an assembly perspective view of the engaged-type capacitive probe of the first embodiment of the instant disclosure.

FIG. 3 is a sectional side schematic view taken along sectional line in FIG. 1.

FIG. 4 is a sectional side schematic view taken along sectional line IV-IV in FIG. 2.

FIG. 5 is an exploded perspective view of an engaged-type capacitive probe of a second embodiment of the instant disclosure.

FIG. 6 is an assembly perspective view of the engaged-type capacitive probe of the second embodiment of the instant disclosure.

FIG. 7 is a sectional side schematic view taken along sectional line VII-VII in FIG. 6.

FIG. 8 is a sectional side schematic view taken along sectional line VIII-VIII in FIG. 7.

FIG. 9 is an exploded perspective view of an engaged-type capacitive probe of a third embodiment of the instant disclosure.

FIG. 10 is an exploded perspective view of an engaged-type capacitive probe of a fourth embodiment of the instant disclosure.

FIG. 11 is an exploded perspective view of an engaged-type capacitive probe of a fifth embodiment of the instant disclosure.

FIG. 12 is an exploded perspective view of an engaged-type capacitive probe of a sixth embodiment of the instant disclosure.

FIG. 13 is an exploded perspective view of the probe assembly of a seventh embodiment of the instant disclosure.

FIG. 14 is an assembly perspective view of the probe assembly of the seventh embodiment of the instant disclosure.

### DESCRIPTION OF THE EXEMPLARY EMBODIMENTS

Reference will now be made in detail to the exemplary embodiments of the instant disclosure, examples of which are illustrated in the accompanying drawings. Wherever possible, the same reference numbers are used in the drawings and the description to refer to the same or like parts.

It is noted that the term “first” and “second” for describing different elements or signals are only used to distinguish these elements/signals from one another rather than limiting the nature thereof. In addition, the term “or” used in the specification may include one or more of the listed items.

### First Embodiment

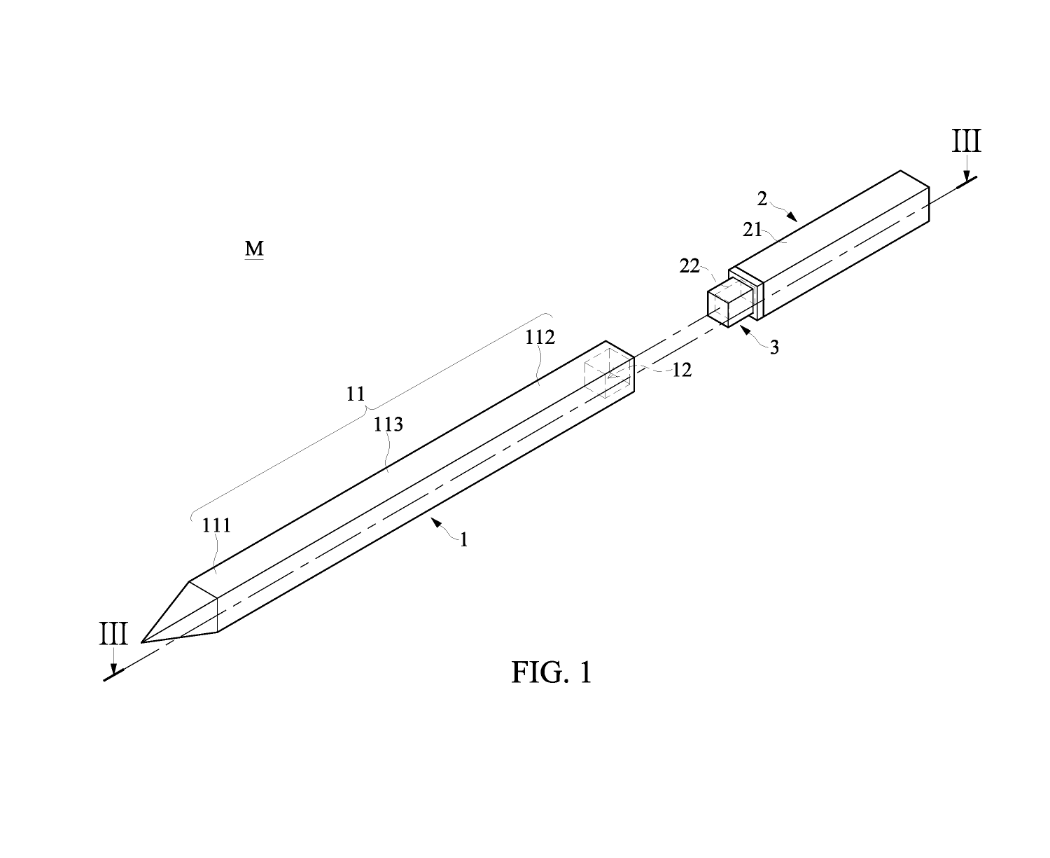

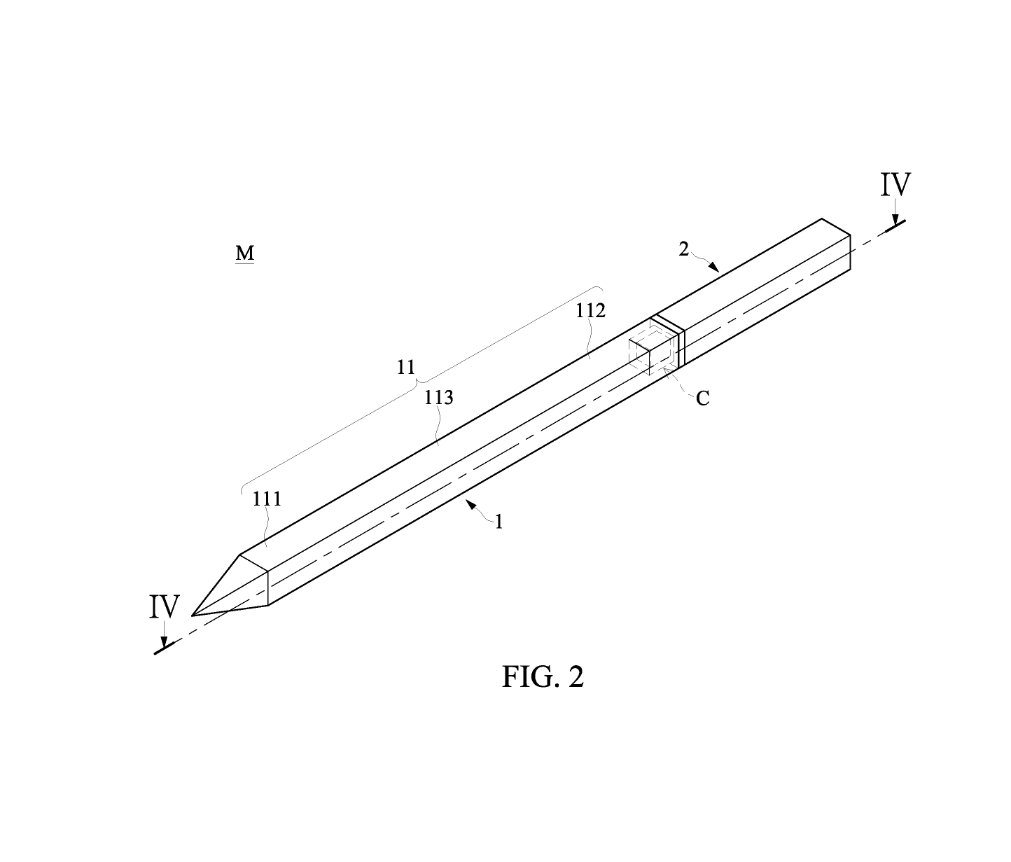

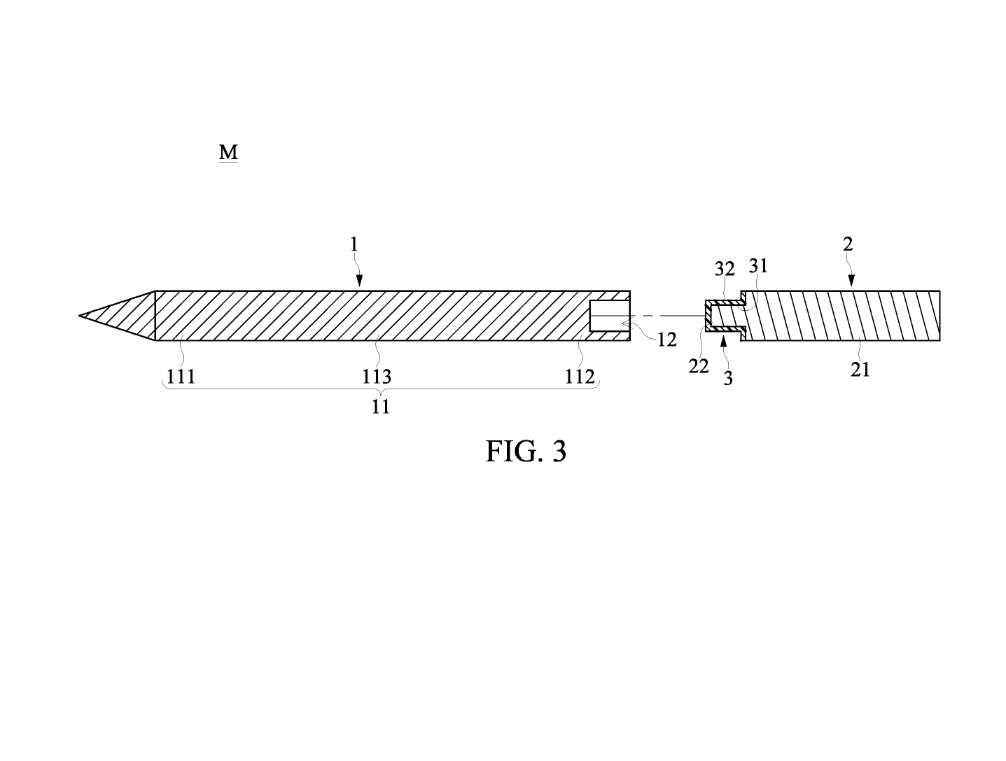

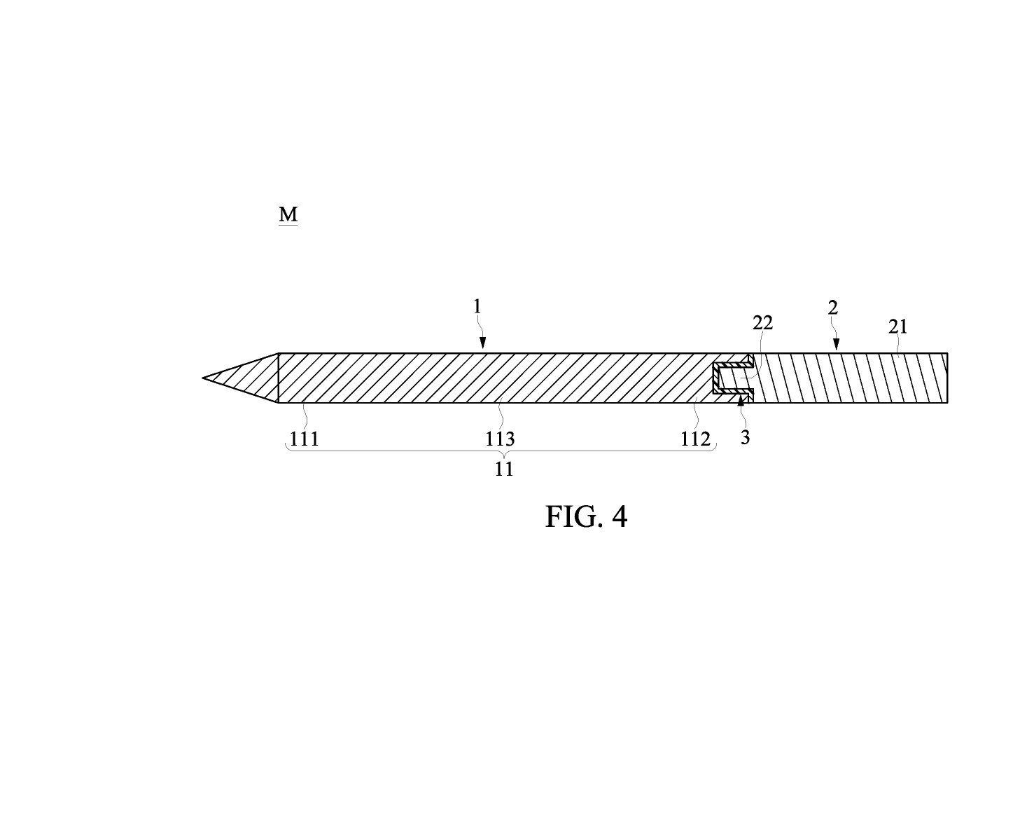

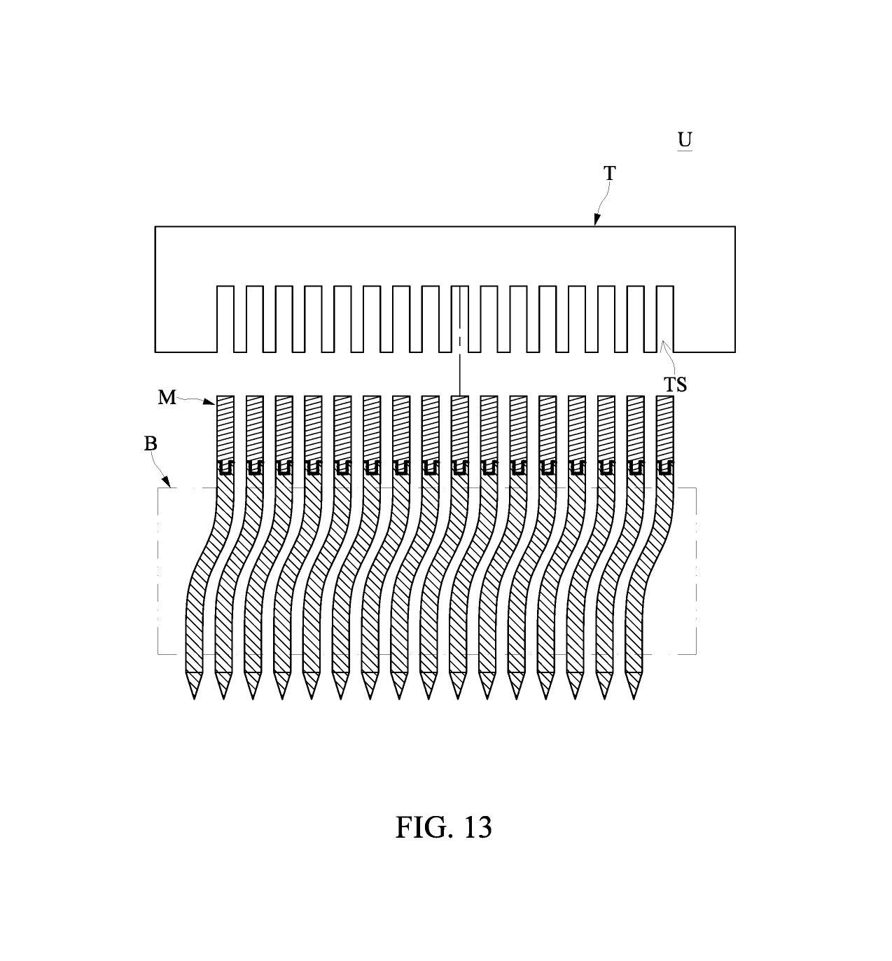

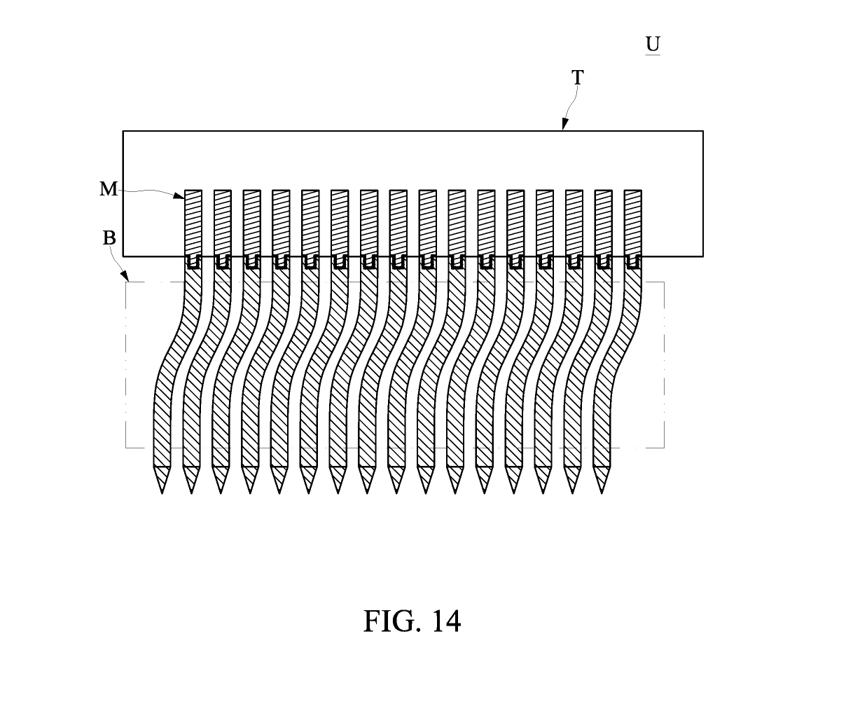

Reference is made to FIG. 1 to FIG. 4, FIG. 13 and FIG. 14. FIG. 1 and FIG. 2 are perspective views of the engaged-type capacitive probe M of the first embodiment of the instant disclosure, FIG. 3 and FIG. 4 are sectional side schematic views of the engaged-type capacitive probe M of the first embodiment of the instant disclosure, and FIG. 13 and FIG. 14 are schematic views of the probe assembly U of the embodiments of the instant disclosure. The instant disclosure provides a probe assembly U and an engaged-type capacitive probe M thereof. The main technical features of the engaged-type capacitive probe M are described in this embodiment, while details regarding the probe assembly U will be described later in other embodiments of the present disclosure. In addition, it should be noted that although the engaged-type capacitive probe M shown in the figures is depicted as a rectangular column, the instant disclosure is not limited thereto and in other implementations, the engaged-type capacitive probe M can have the shape of a cylinder or other shapes. Furthermore, it should be noted that although the engaged-type capacitive probes M are depicted as a linear structure in in FIG. 1 to FIG. 12, in other embodiments of the instant disclosure, the engaged-type capacitive probes M can also have a curved shape such as that shown in shown in FIG. 13 and FIG. 14.

Referring to FIG. 1 to FIG. 4, the engaged-type capacitive probe M can include a probe structure 1, a conductive structure 2 and a dielectric structure 3. The probe structure 1 and the conductive structure 2 can be disposed adjacent to each other. In the embodiments of the instant disclosure, the conductive structure 2 can be disposed at one side of the probe structure 1. In addition, the probe structure 1 has a probe body 11 and a first engaging portion 12 disposed on the probe body 11. The conductive structure 2 can have a conductive body 21 and a second engaging portion 22 disposed on the conductive body 21 and corresponding to the first engaging portion 12. The conductive structure 2 can be disposed on the first engaging portion 12 of the probe structure 1 through the second engaging portion 22. In addition, the dielectric structure 3 can be disposed between the probe structure 1 and the conductive structure 2. In the first embodiment, the dielectric structure 3 can be disposed on the second engaging portion 22 of the conductive structure 2, so that the dielectric structure 3 can be disposed between the first engaging portion 12 of the probe structure 1 and the second engaging portion 22 of the conductive structure 2 for electrically insulating the probe structure 1 and the conductive structure 2 from each other. However, it should be noted that in other implementations, the dielectric structure 3 can be disposed on the first engaging portion 12 of the probe structure 1 or on the probe body 11 thereby allowing the dielectric structure 3 to be located between the probe structure 1 and the conductive structure 2.

In other words, in the first embodiment, the first engaging portion 12 of the probe structure 1 can be a groove or a slot, and the second engaging portion 22 of the conductive structure 2 can be a protrusion. The shape of the first engaging portion 12 can correspond to the shape of the second engaging portion 22. It should be noted that although the first engaging portion 12 is a groove and the second engaging portion 22 is a protrusion in the first embodiment, the first engaging portion 12 can also be a protrusion and the second engaging portion 22 can also be a groove in other implementations. In addition, although the engaging portions are depicted as grooves and protrusion in FIG. 1 to FIG. 4, the engaging portions can have other shapes in the other implementations. The engaging manners between the probe structure 1 and the conductive structure 2 are described in the following embodiments.

Referring to FIG. 3 and FIG. 4, the probe structure 1 can have a first end portion 111, a second end portion 112 corresponding to the first end portion 111, a connecting portion 113 connected between the first end portion 111 and the second end portion 112. In addition, in the embodiments of the instant disclosure, the first engaging portion 12 can be disposed on the second end portion 112. However, in other implementations, the first engaging portion 12 can be disposed on the connecting portion 113, and the instant disclosure is not limited thereto. For example, the first end portion 111 of the probe structure 1 can be in a shape of a pointed needle for breaking the oxidation layer on the surface of the tin ball (i.e., the object to be measured). However, in other embodiments, the first end portion 111 of the probe structure 1 can have a flat surface, and the instant disclosure is not limited thereto. In addition, the second end portion 112 can be a needle tail of the probe structure 1 for being connected to the contacting end of the transferring interface plate (for example, the transfer board T shown in FIG. 13 and FIG. 4).

The probe structure 1 can be made of conductive material and to have conductivity, and the resistivity of the probe structure 1 can be less than 5×10² Ωm. The material of the probe structure 1 can include but not limited to: gold (Au), silver (Ag), copper (Cu), nickel (Ni), cobalt (Co) or any alloy thereof. Preferably, the probe structure 1 can be a composite metal material having conductivity, for example, palladium-nickel alloy, nickel-cobalt alloy, nickel-magnesium alloy, nickel-tungsten alloy, nickel-phosphor alloy or palladium-cobalt alloy. In addition, in other implementations, the outer surface of the probe structure 1 can have covering layers made of different materials and stacked thereon for forming a probe structure 1 with a multi-layer covering structure (not shown in the figures). In addition, the conductive structure 2 has conductivity and a resistivity of less than 5×10² Ωm. The material of the conductive structure 2 can include but not limited to: gold (Au), silver (Ag), copper (Cu), nickel (Ni), cobalt (Co) or the alloy thereof. Furthermore, the conductive structure 2 can be made of a composite metal material having conductivity, for example, palladium-nickel alloy, nickel-cobalt alloy, nickel-magnesium alloy, nickel-tungsten alloy, nickel-phosphor alloy or palladium-cobalt alloy. However, the instant disclosure is not limited thereto.

Referring to FIG. 3 and FIG. 4, the dielectric structure 3 can be disposed between the probe structure 1 and the conductive structure 2 for electrically insulating the probe structure 1 and the conductive structure 2 from each other. In addition, the dielectric structure 3 can have a first surface 31 directly in contact with the probe structure 1 and a second surface 32 directly in contact with the dielectric structure 3. For example, the dielectric structure 3 can be made of an insulating material and have a resistivity of larger than or equal to 10⁸ Ωm, preferably larger than or equal to 10⁹ Ωm. In addition, the material of the dielectric structure 3 can include but not limited to polymer materials or ceramic materials, preferably, aluminum oxide (Al₂O₃). Moreover, in other implementations, the material of the dielectric structure 3 can be silicon nitride, yttrium oxide, titanium oxide, hafnium oxide, zirconium oxide or barium titanate. However, the instant disclosure is not limited thereto. Therefore, a capacitive area C can be formed by the dielectric structure 3 disposed between the probe structure 1 and the conductive structure 2, thereby forming an embedded capacitor in the engaged-type capacitive probe M. In addition, it should be noted that the arrangement of the probe structure 1, the dielectric structure 3 and the conductive structure 2 can be formed by a microelectromechanical system (MEMS) process such as a lithography process and/or an electroplating process.

### Second Embodiment

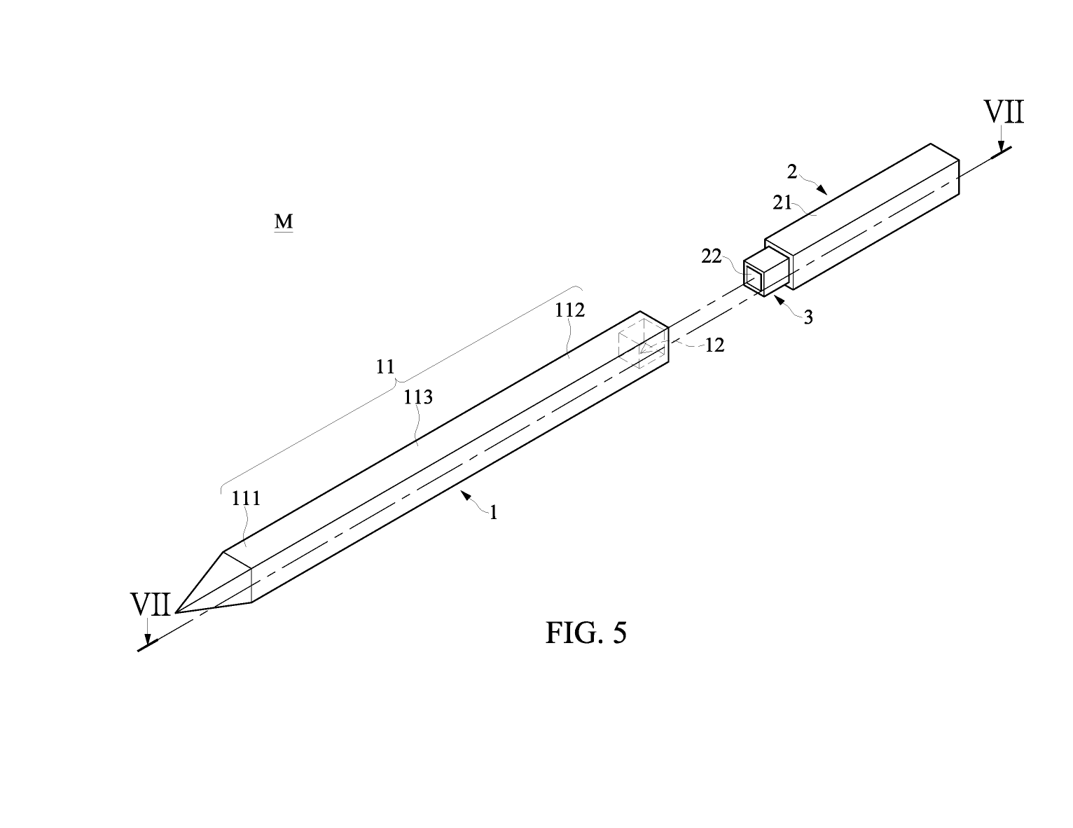

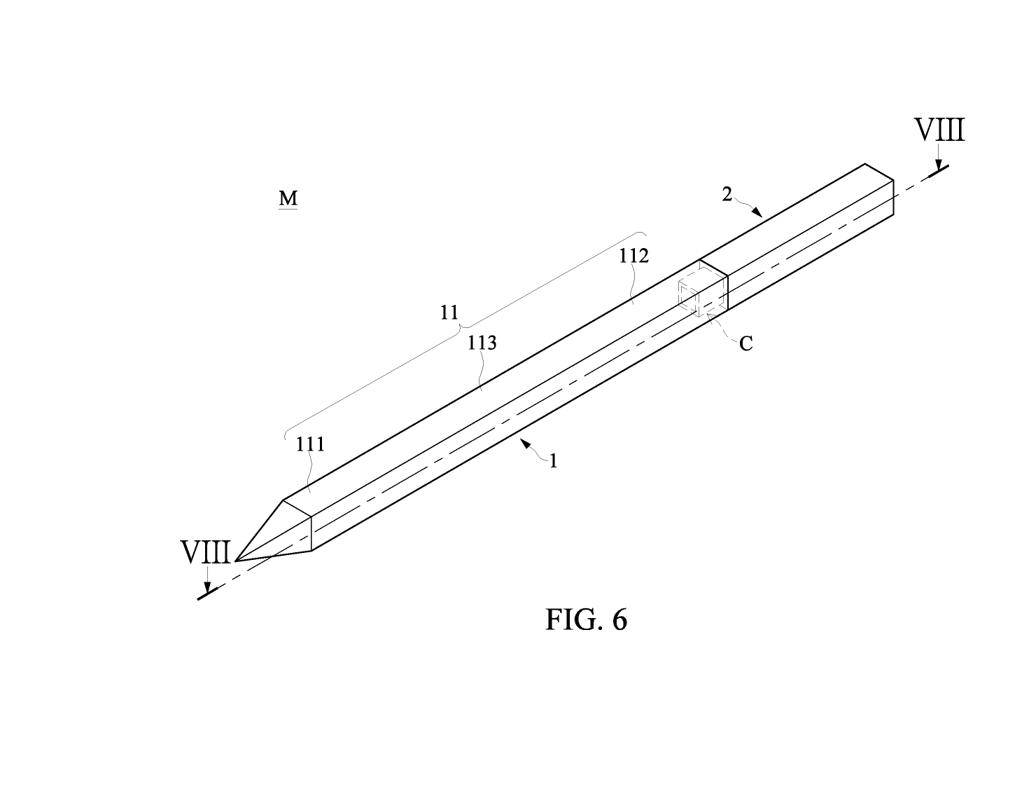

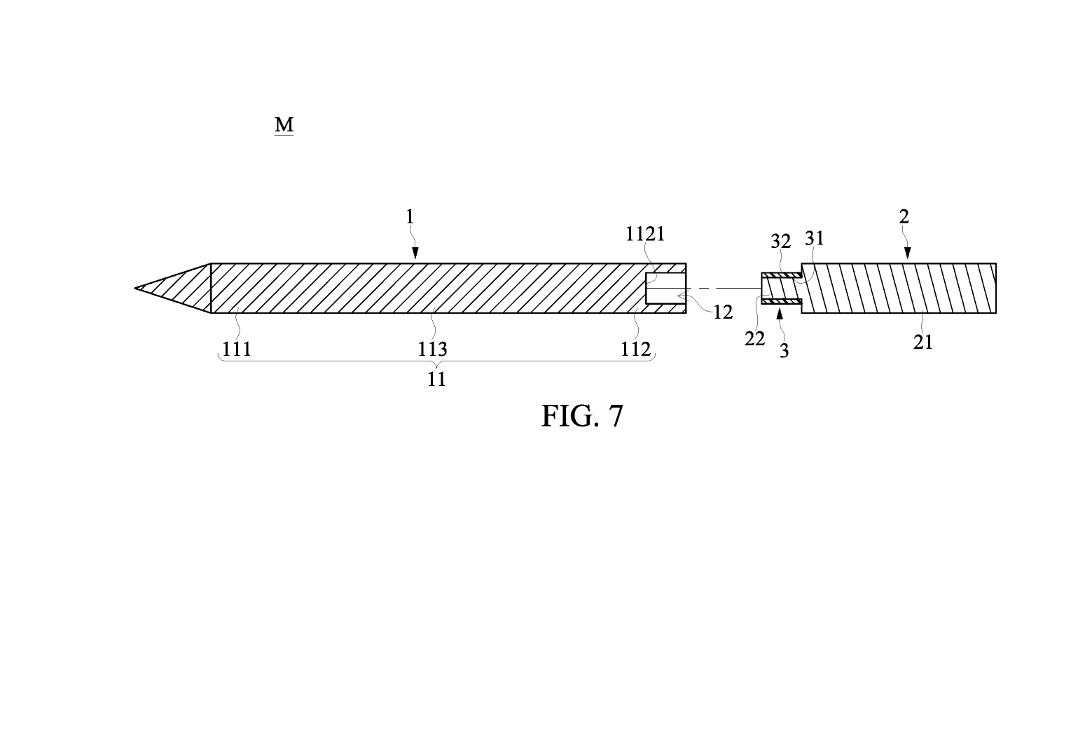

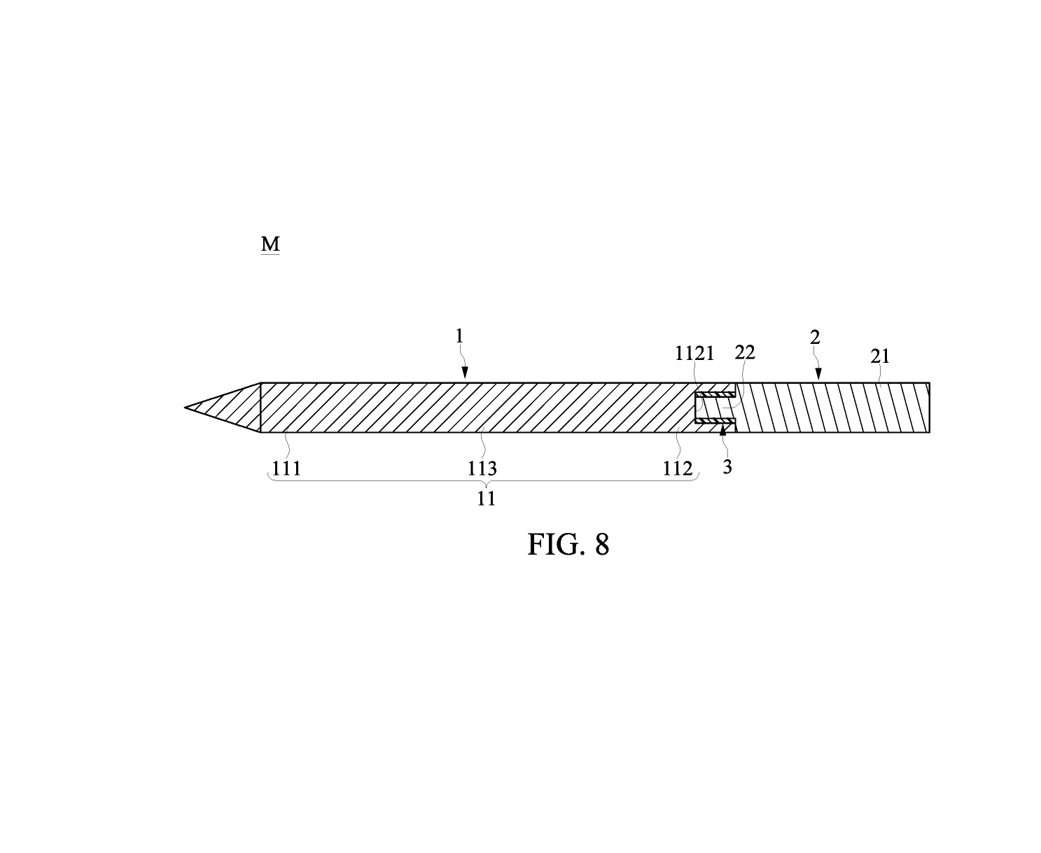

Reference is made to FIG. 5 to FIG. 8. FIG. 5 and FIG. 6 are perspective views of the engaged-type capacitive probe M of the second embodiment of the instant disclosure. FIG. 7 and FIG. 8 are side sectional schematic views of the engaged-type capacitive probe M of the second embodiment of the instant disclosure. Comparing FIG. 8 to FIG. 4, the main difference between the second embodiment and the first embodiment is that the probe structure 1, the conductive structure 2 and the dielectric structure 3 of the engaged-type capacitive probe M provided by the second embodiment are connected in parallel. In addition, it should be noted that the characteristics of the probe structure 1, the conductive structure 2 and the dielectric structure 3 provided by the second embodiment are similar to that of the previous embodiment and are not reiterated herein. In other words, the resistivity, the materials and/or the shape of the probe structure 1, the conductive structure 2 and the dielectric structure 3 can be selected according to the previous embodiment.

Specifically, the probe structure 1 can have an exposed portion 1121 corresponding to the dielectric structure 3, and the probe structure 1 can be electrically connected to the conductive structure 2 through the exposed portion 1121. The dielectric structure 3 has a first surface 31 in contact with the probe structure 1 and a second surface 32 in contact with the conductive structure 2. In other words, the probe structure 1, the conductive structure 2 and the dielectric structure 3 in the engaged-type capacitive probe M provided by the second embodiment are connected in parallel. In addition, it should be noted that in other implementations, the exposed portion 1121 can be located at the side of the second end portion 112 and is a flat surface. In other words, the exposed portion 1121 is an exposed surface of the probe structure 1 opposite to the dielectric structure 3, and the exposed surface is electrically connected to the conductive structure 2.

### Third Embodiment

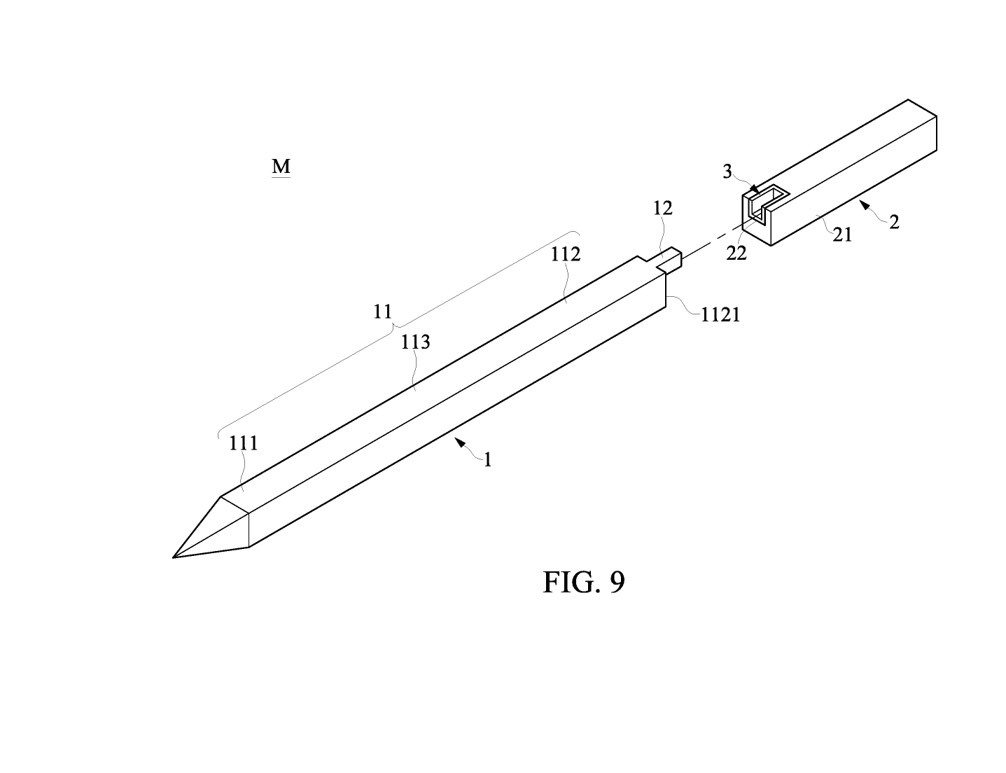

Reference is made to FIG. 9. Comparing FIG. 9 to FIG. 5, the main difference between the third embodiment and the first and second embodiment is that the shapes of the conductive body 21 and the second engaging portion 22 of the engaged-type capacitive probe M provided by the third embodiment are different from that of the previous embodiments. In other words, in the third embodiment, the first engaging portion 12 can be a protrustion and the second engaging portion 22 can be a groove-like structure. In addition, the dielectric structure 3 can be disposed on the second engaging portion 22, so that the dielectric structure 3 can be located between the first engaging portion 12 and the second engaging portion 22.

As shown in FIG. 9, in this embodiment, the probe structure 1 can have an exposed portion 1121 corresponding to the dielectric structure 3, and the probe structure 1 can be electrically connected to the conductive structure 2 through the exposed portion 1121. In other words, the probe structure 1, the conductive structure 2 and the dielectric structure 3 can form a structure in which the components are connected in parallel. However, in other implementations, the dielectric structure 3 can completely isolate the first engaging portion 12 and the second engaging portion 22 from each other for electrically insulating the probe structure 1 and the conductive structure 2 from each other. In addition, it should be noted that the characteristics of the probe structure 1, the conductive structure 2 and the dielectric structure 3 provided by the third embodiment are similar to that of the previous embodiments and are not reiterated herein.

### Fourth Embodiment

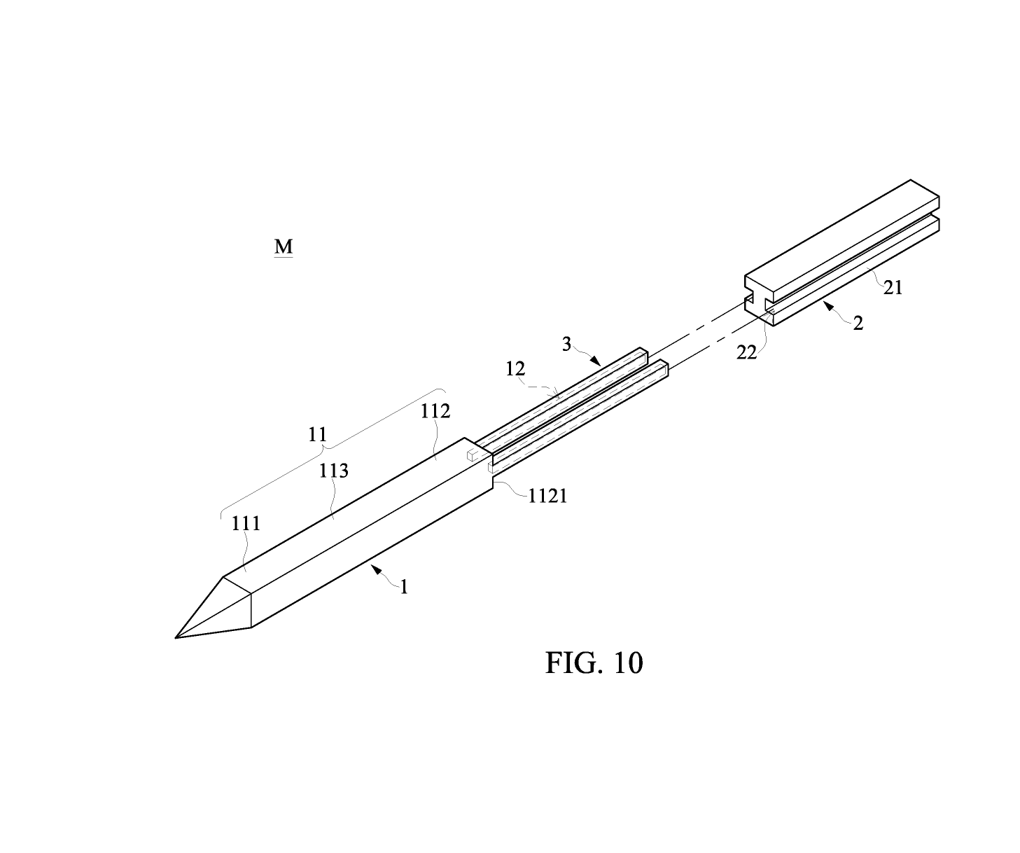

Reference is made to FIG. 10. Comparing FIG. 10 to FIG. 9, the main difference between the fourth embodiment and the third embodiment is that the shapes of the first engaging portion 12 and the second engaging portion 22 of the engaged-type capacitive probe M provided by the fourth embodiment are different from that of the previous embodiments. In other words, in the fourth embodiment, the first engaging portion 12 of the probe structure 1 can have a double-protrusion structure, and the second engaging portion 22 of the conductive structure 2 can have a double-groove structure. Therefore, the second engaging portion 22 would have an I-shape structure. In addition, the characteristics of the probe structure 1, the conductive structure 2 and the dielectric structure 3 provided by the fourth embodiment are similar to that of the previous embodiments and are not reiterated herein.

Furthermore, in the embodiment shown in FIG. 10, the probe structure 1 can have an exposed portion 1121 corresponding to the dielectric structure 3, and the probe structure 1 can be electrically connected to the conductive structure 2 through the exposed portion 1121. In other words, the probe structure 1, the conductive structure 2 and the dielectric structure 3 can form a structure in which the components are connected in parallel. However, it should be noted that in other implementations, the dielectric structure 3 can completely isolate the first engaging portion 12 and the second engaging portion 22 from each other for electrically insulating the probe structure 1 and the conductive structure 2 from each other.

### Fifth Embodiment

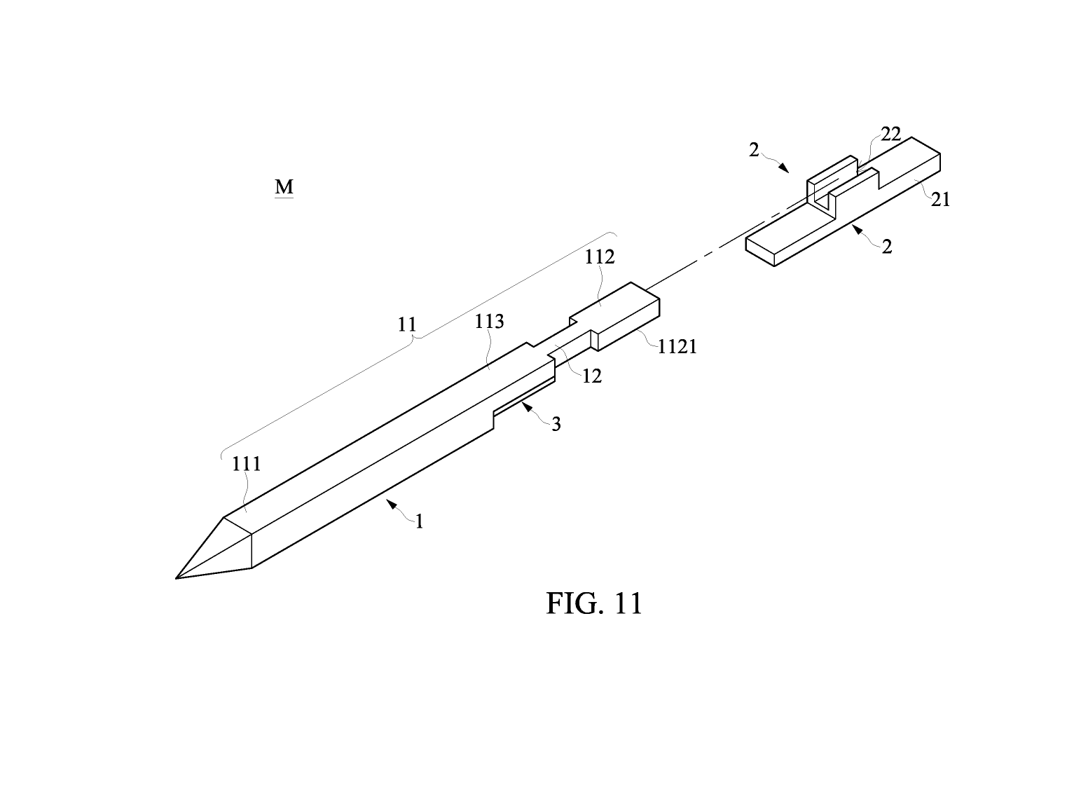

Reference is made to FIG. 11. Comparing FIG. 11 to FIG. 9, the main difference between the fifth embodiment and the third embodiment resides in that the shapes of the first engaging portion 12 and the second engaging portion 22 of the engaged-type capacitive probe M provided by the fifth embodiment are different than that of the previous embodiments. In other words, the first engaging portion 12 can be disposed on the connecting portion 113 of the probe structure 1, and hence, in the implementation shown in FIG. 11, the first engaging portion 12 is long and narrow compared to the first end portion 111 and the second end portion 112. In addition, the second engaging portion 22 can be a groove for accommodating the first engaging portion 12. Moreover, the dielectric structure 3 can be disposed on the connecting portion 113, and be located between the probe structure 1 and the conductive structure 2.

It should be noted that the characteristics of the probe structure 1, the conductive structure 2 and the dielectric structure 3 provided by the fifth embodiment are similar to that of the previous embodiments and are not reiterated herein. In addition, the dielectric structure 3 can be disposed between the probe structure 1 and the conductive structure 2, and based on whether or not the exposed portion 1121 is present, the probe structure 1, the conductive structure 2 and the dielectric structure 3 can be connected in series or in parallel.

### Sixth Embodiment

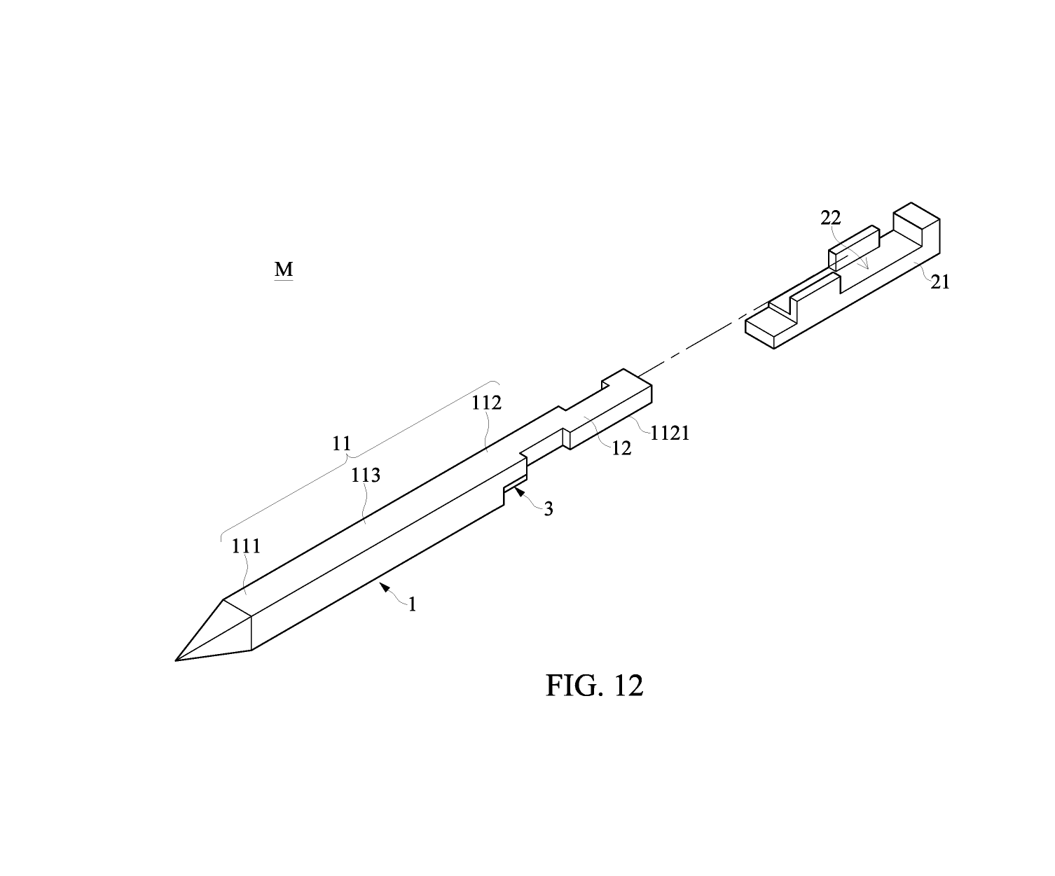

Reference is made to FIG. 12. Comparing FIG. 12 to FIG. 11, the main difference between the sixth embodiment and the fifth embodiment is that the shapes of the first engaging portion 12 and the second engaging portion 22 of the engaged-type capacitive probe M provided by the sixth embodiment are different than that of the previous embodiments. In other words, the sixth embodiment can have two first engaging portions 12 and two second engaging portions 22. The two first engaging portions 12 both have a structure which is long and narrow compared to the first end portion 111 and the second end portion 112. In addition, the two second engaging portions 22 can be two grooves for accommodating the two first engaging portions 12.

It should be noted that the characteristics of the probe structure 1, the conductive structure 2 and the dielectric structure 3 provided by the sixth embodiment are similar to that of the previous embodiments and are not reiterated herein. In addition, the dielectric structure 3 can be disposed between the probe structure 1 and the conductive structure 2, and based on whether or not of the exposed portion 1121 is present, the probe structure 1, the conductive structure 2 and the dielectric structure 3 can be connected in series or in parallel.

### Seventh Embodiment

Reference is made to FIG. 13 and FIG. 14. FIG. 13 and FIG. 14 are the schematic views of the probe assembly U of the embodiments of the instant disclosure. The seventh embodiment of the instant disclosure provides a probe assembly U including a transfer board T, a probe bearing seat B and a plurality of engaged-type capacitive probes M. The transfer board T can have a plurality of accommodating grooves TS. The probe bearing seat B can be disposed on the transfer board T, and the plurality of engaged-type capacitive probes M can be disposed on the probe bearing seat B. In addition, the plurality of engaged-type capacitive probes M can be disposed in the plurality of accommodating grooves of the transfer board T. It should be noted that the manner of connection between the transfer board T and the probe bearing seat B is well-known in the art and is not described in detail herein.

Referring to FIG. 13, FIG. 14 and FIG. 4, the engaged-type capacitive probes M used in the seventh embodiment are exemplified as the engaged-type capacitive probe M provided in the first embodiment. However, in other implementations, any one of the engaged-type capacitive probe M provided by the previous embodiments can be also used.

In the seventh embodiment of the instant disclosure, the conductive structure 2 of each of the engaged-type capacitive probes M can be electrically connected to the transfer board T for feeding the power and/or the ground voltage to the engaged-type capacitive probe M. In addition, it should be noted that the structure of the engaged-type capacitive probe M is already described in the previous embodiments and is not reiterated herein.

### Effectiveness of the Embodiments

One of the advantages of the instant disclosure is that the probe assembly U and the engaged-type capacitive probe M thereof provided by the embodiments of the instant disclosure can optimize the target impedance value and increase the performance of the power delivery network based on the technical feature of “the dielectric structure 3 is disposed between the first engaging portion 12 of the probe structure 1 and the second engaging portion 22 of the conductive structure 2”.

The above-mentioned descriptions represent merely the exemplary embodiment of the present disclosure, without any intention to limit the scope of the instant disclosure thereto. Various equivalent changes, alterations or modifications based on the claims of the instant disclosure are all consequently viewed as being embraced by the scope of the instant disclosure.

What is claimed is:

1. An engaged-type capacitive probe, including:
a probe structure having a probe body and a first engaging portion disposed on the probe body;
a conductive structure disposed at one side of the probe structure, the conductive structure having a second engaging portion corresponding to the first engaging portion, the conductive structure being disposed on the first engaging portion of the probe structure through the second engaging portion; and
a dielectric structure disposed between the probe structure and the conductive structure.

2. The engaged-type capacitive probe according to claim 1, wherein the probe structure has an exposed portion corresponding to the dielectric structure, and the probe structure is electrically connected to the conductive structure through the exposed portion, wherein the dielectric structure has a first surface in contact with the probe structure and a second surface in contact with the conductive structure.

3. The engaged-type capacitive probe according to claim 1, wherein the probe structure and the conductive structure are electrically insulated from each other, and the dielectric structure has a first surface in contact with the probes structure and a second surface in contact with the conductive structure.

4. The engaged-type capacitive probe according to claim 1, wherein the dielectric structure is disposed between the first engaging portion of the probe structure and the second engaging portion of the conductive structure.

5. The engaged-type capacitive probe according to claim 1, wherein the probe structure has a resistivity of less than 5×10² Ωm.

6. The engaged-type capacitive probe according to claim 1, wherein the conductive structure has a resistivity of less than 5×10² Ωm.

7. The engaged-type capacitive probe according to claim 1, wherein the dielectric structure has a resistivity of more than or equal to 10⁸ Ωm.

8. A probe assembly, including:
a transfer board having a plurality of accommodating grooves;
a probe bearing seat disposed on the transfer board; and
a plurality of engaged-type capacitive probes disposed on the probe bearing seat and respectively in the plurality of accommodating grooves, wherein each of the engaged-type capacitive probes includes a probe structure, a conductive structure and a dielectric structure;
wherein the probe structure has a probe body and a first engaging portion disposed on the probe body, the conductive structure is disposed at one side of the probe structure, the conductive structure has a second engaging portion corresponding to the first engaging portion, the conductive structure is disposed on the first engaging portion of the probe structure through the second engaging portion, and the dielectric structure is disposed between the first engaging portion of the probe structure and the second engaging portion of the conductive structure.

9. The probe assembly according to claim 8, wherein the probe structure has an exposed portion corresponding to the dielectric structure, and the probe structure is electrically connected to the conductive structure through the exposed portion, wherein the dielectric structure has a first surface in contact with the probe structure and a second surface in contact with the conductive structure.

10. The probe assembly according to claim 8, wherein the probe structure and the conductive structure are electrically insulated from each other and the dielectric structure has a first surface in contact with the probe structure and a second surface in contact with the conductive structure.
